(19) United States
(12) Patent Application Publication
(10) Pub. No.: US 2026/0181865 A1
(43) Pub. Date: Jun. 25, 2026

(54) SEMICONDUCTOR DEVICE AND METHOD FOR FABRICATING THE SAME

(71) Applicant: SK hynix Inc., Gyeonggi-do (KR)

(72) Inventors: Kyung Kyu MIN, Gyeonggi-do (KR); Seong Wan RYU, Gyeonggi-do (KR); Ah Rahm LEE, Gyeonggi-do (KR)

(21) Appl. No.: 19/224,907

(22) Filed: Jun. 2, 2025

(30) Foreign Application Priority Data
Dec. 24, 2024 (KR) 10-2024-0195430

(51) Int. Cl. H10B 12/00; H10D 30/63; H10D 62/10; H10D 64/27; H10D 64/66

(52) U.S. Cl. CPC H10B 12/315; H10B 12/482; H10B 12/488; H10D 30/63; H10D 62/102; H10D 64/519; H10D 64/669; H10B 12/05

(57) ABSTRACT

Disclosed are a semiconductor device capable of preventing Gate Induced Drain Leakage (GIDL), and a method for fabricating the semiconductor device. The semiconductor device and the fabrication method thereof may have a reduced unit cell area and improved channel layer characteristics. A semiconductor device includes a semiconductor pillar formed over a substrate; a word line formed on a first sidewall of the semiconductor pillar; a conductive pattern formed on a second sidewall of the semiconductor pillar; and a work function pattern locally formed between the semiconductor pillar and the word line.

### CROSS-REFERENCE TO RELATED APPLICATIONS

The present application claims priority under 35 U.S.C 119(a) to Korean Patent Application No. 10-2024-0195430, filed on Dec. 24, 2024, which is incorporated herein by reference in its entirety.

### BACKGROUND

### 1. Field

Embodiments of the present disclosure relate generally to a semiconductor device and a method for fabricating the same, and more particularly, to a semiconductor device including a vertical gate, and a method for fabricating the semiconductor device.

### 2. Description of the Related Art

As the design rules for semiconductor devices continue to shrink, enabling smaller feature sizes, the integration density of these devices increases significantly. This trend, while beneficial for achieving higher performance and functionality, introduces challenges such as short-channel effects and limitations in planar transistor designs. To address these issues, a transistor with a vertical channel has been proposed. However, further improvements are needed.

### SUMMARY

Embodiments of the present disclosure are directed to a semiconductor device that prevents Gate Induced Drain Leakage (GIDL), and a method for fabricating the semiconductor device.

In accordance with an embodiment of the present disclosure, a semiconductor device includes a semiconductor pillar formed in an upper portion of a substrate; a word line formed on a first sidewall of the semiconductor pillar; a conductive pattern formed on a second sidewall of the semiconductor pillar; and a work function pattern locally formed between the semiconductor pillar and the word line.

In accordance with another embodiment of the present disclosure, a semiconductor device includes a semiconductor pillar having first and second doped regions respectively formed at both ends over a substrate, and including a channel region between the first doped region and the second doped regions; a gate dielectric layer on both sidewalls of the semiconductor pillar; a gate electrode over the gate dielectric layer of a first sidewall of the semiconductor pillar; a conductive pattern over the gate dielectric layer of a second sidewall of the semiconductor pillar; and a work function pattern locally formed between the gate dielectric layer and the gate electrode.

In accordance with another embodiment of the present disclosure, a method for fabricating a semiconductor device includes forming a semiconductor pillar including a first doped region, a channel region, and a second doped region over a substrate; forming a gate dielectric layer on both sidewalls of the semiconductor pillar; forming a first low work function inducing material over the gate dielectric layer of both sidewalls of the semiconductor pillar; forming a first metal electrode and a first conductive electrode, each of which partially overlaps with the first doped region, over the first low work function inducing material on both sidewalls of the semiconductor pillar; forming a first work function pattern that has an upper surface at the same level as the first metal electrode and the first conductive electrode and exposes the gate dielectric layer by etching the first low work function inducing material; forming a second metal electrode and a second conductive electrode each of which overlaps with the channel region over the gate dielectric layer exposed in the upper portion of the first work function pattern; forming a second low work function inducing material over the gate dielectric layer exposed in the upper portions of the second metal electrode and the second conductive electrode; forming a third metal electrode and a third conductive electrode each of which partially overlaps with the second doped region over the second low work function inducing material; and forming a second work function pattern by etching the second low work function inducing material.

### BRIEF DESCRIPTION OF THE DRAWINGS

FIG. 1 is a plan view illustrating a semiconductor device in accordance with an embodiment of the present disclosure.

FIG. 2 is a cross-sectional view of the semiconductor device taken along a line A-A′ shown in FIG. 1.

FIGS. 3A to 3I are process cross-sectional views illustrating a method for fabricating a semiconductor device in accordance with an embodiment of the present disclosure.

FIGS. 4 to 7 are plan views illustrating semiconductor devices in accordance with other embodiments of the present disclosure.

FIGS. 8 to 13 are cross-sectional views illustrating semiconductor devices in accordance with other embodiments of the present disclosure.

FIG. 14 is a plan view illustrating a semiconductor device in accordance with another embodiment of the present disclosure.

FIG. 15 is a cross-sectional view of the semiconductor device taken along a line A-A′ shown in FIG. 14.

FIGS. 16 and 17 are plan views illustrating a semiconductor device in accordance with other embodiments of the present disclosure.

### DETAILED DESCRIPTION

Embodiments of the present disclosure will be described below in more detail with reference to the accompanying drawings. The embodiments of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

Hereinafter, the various embodiments of the present disclosure will be described in detail with reference to the attached drawings. The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

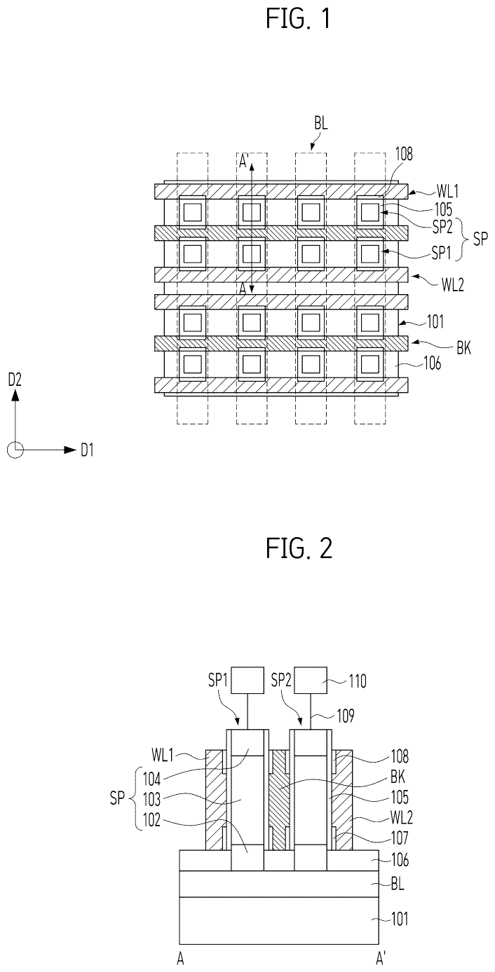

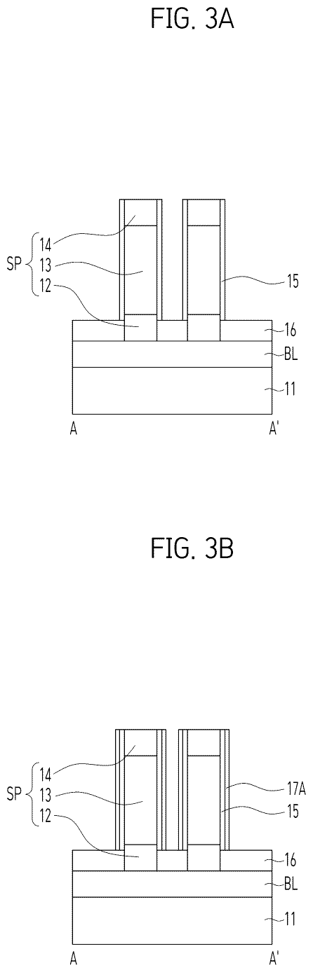

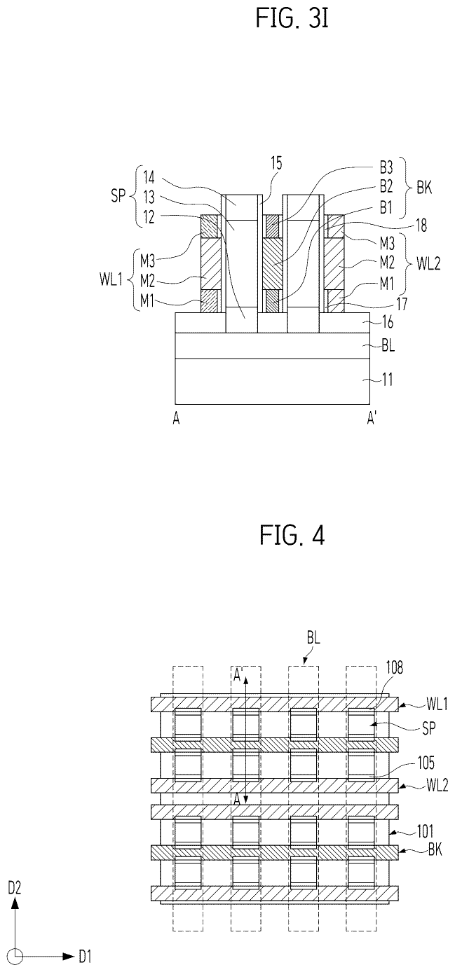

FIG. 1 is a plan view illustrating a semiconductor device in accordance with an embodiment of the present disclosure. FIG. 2 is a cross-sectional view of the semiconductor device taken along a line A-A′ shown in FIG. 1. FIGS. 4 to 7 are plan views illustrating semiconductor devices in accordance with other embodiments of the present disclosure. FIG. 8 is a cross-sectional view illustrating a semiconductor device in accordance with another embodiment of the present disclosure.

Referring to FIGS. 1 and 2, the semiconductor device may include a semiconductor pillar SP having doped regions respectively formed at both ends of the semiconductor pillar SP, a gate dielectric layer 105 formed on both sidewalls of the semiconductor pillar SP, word lines WL1 and WL2 each of which is formed over the gate dielectric layer 105 on a first side of the semiconductor pillar SP, and a conductive pattern BK formed over the gate dielectric layer 105 on a second side of the semiconductor pillar SP. In particular, according to an embodiment of the present disclosure, the semiconductor device may further include a work function pattern 108 which is locally formed between the gate dielectric layer 105 and the word lines WL1 and WL2. The semiconductor pillar SP may be formed over substrate 101.

The substrate 101 may be a material appropriate for semiconductor processing. The substrate 101 may include a semiconductor substrate. The substrate 101 may be formed of a silicon-containing material. The substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may also include another semiconductor material, such as germanium. The substrate 101 may also include a III/V-group semiconductor substrate, for example, a compound semiconductor substrate, such as gallium arsenide (GaAs). The substrate 101 may also include an SOI (Silicon-On-Insulator) substrate.

A plurality of bit lines BL may be disposed over the substrate 101. Each of the bit lines BL may extend in a second direction D2. The bit lines BL may be spaced apart from each other in a first direction D1. The first direction D1 may be orthogonal to the second direction D2.

Each bit line BL may include a metal material, for example, titanium (Ti), titanium nitride (TiN), tantalum (Ta), tantalum nitride (TaN), molybdenum (Mo), ruthenium (Ru), tungsten (W), tungsten nitride (WN), titanium silicon nitride (TiSiN), tungsten silicon nitride (WSiN), polysilicon, or a combination thereof, however, the embodiments of the present invention disclosure are not limited thereto. Each bit line BL may further include a conductive barrier in the upper and lower portions thereof.

A plurality of semiconductor pillars SP may be disposed on the upper portions of the bit lines BL, respectively. The semiconductor pillars SP may be spaced apart from each other in the second direction D2. The semiconductor pillars SP may have a matrix arrangement in which the semiconductor pillars SP are spaced apart from each other by a predetermined interval in the first direction D1 and the second direction D2.

The semiconductor pillars SP which are disposed spaced apart from each other in the second direction D2 may be arranged in pairs, each pair having a first semiconductor pillar SP1 and a second semiconductor pillar SP2. Each pair of the semiconductor pillars SP may include a first semiconductor pillar SP1 and a second semiconductor pillar SP2 that are spaced apart from each other in the second direction D2.

A conductive pattern BK may be disposed between the first semiconductor pillar SP1 and the second semiconductor pillar SP2 of the pair. The conductive pattern BK may serve to shield the interference between the neighboring word lines and may be referred to as a ‘shielding pattern BK’. The pair of the first semiconductor pillar SP1 and the second semiconductor pillar SP2 may share one conductive pattern BK. The facing sidewalls of the first semiconductor pillar SP1 and the second semiconductor pillar SP2 may be formed on both sidewalls of the conductive pattern BK, respectively. The first word line WL1 and the second word line WL2 may be formed on the sidewalls of the first and second semiconductor pillars SP1 and SP2 that are not adjacent to the conductive pattern BK, respectively.

The spacing between the first semiconductor pillar SP1 and the second semiconductor pillar SP2 may be narrower than the spacing between a neighboring pair of semiconductor pillars SP.

Each semiconductor pillar SP may extend in a direction perpendicular to the surface of the substrate 101. Each semiconductor pillar SP may include a first doped region 102 and a second doped region 104 at both ends thereof, and a channel region 103 disposed between the first and second doped regions 102 and 104. The first and second doped regions 102 and 104 may function as a source region or a drain region, respectively. For example, when the first doped region 102 is a source region, the second doped region 104 may be a drain region.

According to an embodiment of the present disclosure, each semiconductor pillar SP may have a rectangular pillar shape, however, the embodiments of the present disclosure are not limited thereto. The semiconductor pillars SP may directly contact the bit lines BL. In particular, as shown in FIG. 2, the first doped regions 102 of the semiconductor pillars SP may directly contact the bit lines BL.

A supporting dielectric layer 106 may be formed between the semiconductor pillars SP. The supporting dielectric layer 106 may be disposed between the neighboring semiconductor pillars SP. The supporting dielectric layer 106 may serve as a support that supports the semiconductor pillars SP. The height of the supporting dielectric layer 106 may be lower than the height of the first doped region 102 of the semiconductor pillars SP. The upper surface of the supporting dielectric layer 106 may be disposed at a lower level than the upper surface of the first doped region 102. For example, the supporting dielectric layer 106 may include silicon oxide, however, the embodiments of the present disclosure are not limited thereto.

According to another embodiment of the present disclosure, the supporting dielectric layer 106 may include an air gap.

The gate dielectric layer 105 may be disposed between the semiconductor pillar SP and the first and second word lines WL1 and WL2. The gate dielectric layer 105 may be disposed between the semiconductor pillar SP and the conductive pattern BK. For example, the gate dielectric layer 105 may include silicon oxide.

The gate dielectric layer 105 may be formed to surround the entire side surface of the semiconductor pillar SP. The gate dielectric layer 105 may be formed with a uniform thickness on the entire side surface of the semiconductor pillar SP.

According to other embodiments of the present disclosure, the gate dielectric layer 105 may be formed only on both sidewalls of the semiconductor pillar SP, as illustrated in FIGS. 4 to 6. The gate dielectric layer 105 may be disposed only between the semiconductor pillar SP and the first and second word lines WL1 and WL2, and between the semiconductor pillar SP and the conductive pattern BK.

Referring to FIG. 4, the gate dielectric layer 105 may be formed with the same thickness on both sidewalls of the semiconductor pillar SP. The thickness of the gate dielectric layer 105 formed between the semiconductor pillar SP and the first and second word lines WL1 and WL2 may be the same as the thickness of the gate dielectric layer 105 which is formed between the semiconductor pillar SP and the conductive pattern BK.

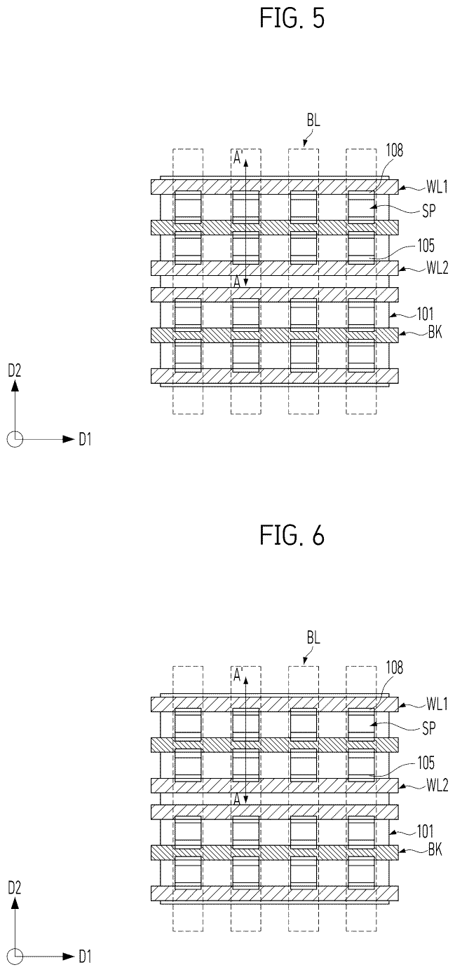

Referring to FIGS. 5 and 6, the gate dielectric layer 105 may be formed with different thicknesses on both sidewalls of the semiconductor pillar SP.

For example, referring to FIG. 5, the gate dielectric layer 105 may be formed such that the thickness of the gate dielectric layer 105 formed between the semiconductor pillar SP and the first and second word lines WL1 and WL2 is thicker than the thickness of the gate dielectric layer 105 formed between the semiconductor pillar SP and the conductive pattern BK.

According to another embodiment of the present disclosure, the gate dielectric layer 105 may be formed such that the thickness of the gate dielectric layer 105 formed between the semiconductor pillar SP and the first and second word lines WL1 and WL2 is thinner than the thickness of the gate dielectric layer 105 formed between the semiconductor pillar SP and the conductive pattern BK, as illustrated in FIG. 6.

The first word line WL1 may be formed over the gate dielectric layer 105 of a first sidewall of the first semiconductor pillar SP1. The first word line WL1 may extend in the first direction D1. The plurality of word lines may be spaced apart from each other in the second direction D2.

The second word line WL2 may be formed over the gate dielectric layer 105 of a second sidewall of the first semiconductor pillar SP2. The second word line WL2 may extend in the first direction D1. The word lines may be spaced apart from each other in the second direction D2.

The conductive pattern BK may be formed between the first word line WL1 and the second word line WL2. The conductive pattern BK may be formed between the first semiconductor pillar SP1 and the second semiconductor pillar SP2. The conductive patterns BK may each extend in the first direction D1. The conductive patterns BK may be spaced apart from each other in the second direction D2. Both sides of the conductive pattern BK may be adjacent to the first semiconductor pillar SP1 and the second semiconductor pillar SP2, respectively. A first sidewall of the conductive pattern BK may be adjacent to the second sidewall of the first semiconductor pillar SP1, and a second sidewall of the conductive pattern BK may be adjacent to the first sidewall of the second semiconductor pillar SP. The gate dielectric layer 105 may be disposed between the conductive pattern BK and the first and second semiconductor pillars SP1 and SP2.

The first and second word lines WL1 and WL2 and the conductive pattern BK may extend in the first direction D1 parallel to both sidewalls of the first and second semiconductor pillars SP1 and SP2. The first and second word lines WL1 and WL2 and the conductive pattern BK may have a line shape extending in the first direction D1.

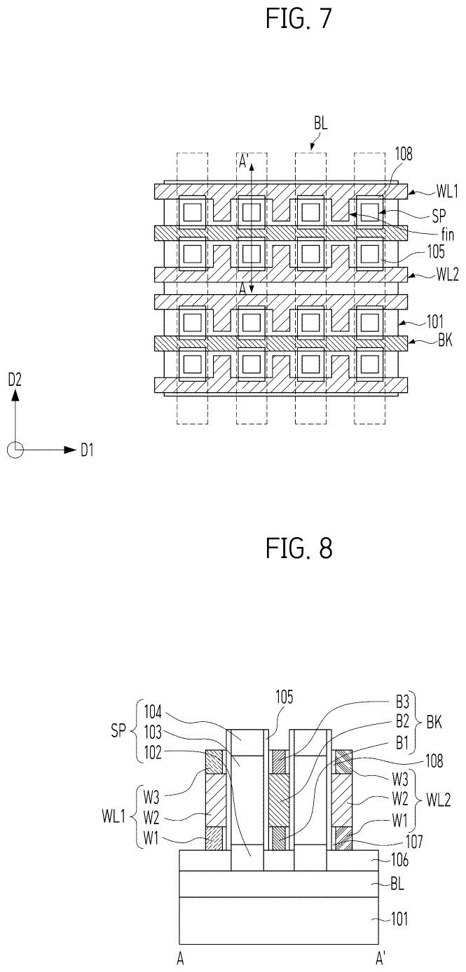

According to another embodiment of the present disclosure, as illustrated in FIG. 7, the first and second word lines WL1 and WL2 may include fins that extend between the semiconductor pillars SP. Specifically, one fin may be disposed between two adjacent semiconductor pillars SP. The fins may extend in the second direction and may be spaced apart from each other in the first direction.

The first and second word lines WL1 and WL2 and the conductive pattern BK may include the same material. The first and second word lines WL1 and WL2 and the conductive pattern BK may include a metal material, for example, a metal nitride, such as titanium nitride (TiN), titanium aluminum nitride (TiAlN), tungsten nitride (WN), and tantalum nitride (TaN), or a low-resistance metal material, such as tungsten (W), aluminum (Al), ruthenium (Ru), platinum (Pt), and gold (Au). According to another embodiment of the present disclosure, the metal material for the first and second word lines WL1 and WL2 and the conductive pattern BK may include molybdenum (Mo).

According to another embodiment of the present disclosure, the first and second word lines WL1 and WL2 and the conductive pattern BK may include different metal materials. According to yet another embodiment of the present disclosure, the first and second word lines WL1 and WL2 may include a metal material, and the conductive pattern BK may include polysilicon.

According to another embodiment of the present disclosure, as illustrated in FIG. 8, each of the first and second word lines WL1 and WL2 may include a stacked structure of different metal materials. Each of the first word line WL1 and the second word line WL2 may include a stacked structure of first to third metal electrodes W1, W2 and W3. The first to third metal electrodes W1, W2 and W3 may be formed of at least one metal material. The conductive pattern BK may include a stacked structure of the first to third conductive electrodes B1, B2 and B3. The first to third conductive electrodes B1, B2 and B3 may include the same material. According to another embodiment of the present disclosure, the first to third conductive electrodes B1, B2 and B3 may include different materials. The first to third conductive electrodes B1, B2 and B3 may include the same material as those of the first to third metal electrodes W1, W2 and W3, respectively.

According to the embodiment illustrated in FIG. 8, the vertical channel transistor may have a double-gate structure. Accordingly, the word lines WL1 and WL2 and the conductive patterns BK are formed on both sidewalls of a semiconductor pillar SP. Each of the word lines WL1 and WL2 may be a gate electrode of the vertical channel transistor. The conductive patterns BK may shield an electric field formed by a neighboring gate, i.e., the neighboring word lines WL1 and WL2. Therefore, the neighboring gate effect may be minimized.

In particular, the embodiment of the present disclosure may include work function patterns 107 and 108 locally formed between the gate dielectric layer 105 and the word lines WL1 and WL2. The work function patterns 107 and 108 may be formed between the gate dielectric layer 105 and the word lines WL1 and WL2, and also between the gate dielectric layer 105 and the conductive pattern BK.

The work function patterns 107 and 108 may include a first work function pattern 107 and a second work function pattern 108. The first work function pattern 107 may partially overlap with the first doped region 102 and the channel region 103 in the horizontal direction, i.e., a direction parallel to the top surface of the substrate. The second work function pattern 108 may partially overlap with the second doped region 104 and the channel region 103 in the horizontal direction.

The first and second work function patterns 107 and 108 may include a low work function material. The first and second work function patterns 107 and 108 may include materials that may induce a low work function by forming a dipole at the interface with the gate dielectric layer 105. For example, the first and second work function patterns 107 and 108 may include lanthanum oxide (LaO). According to another embodiment of the present disclosure, the first and second work function patterns 107 and 108 may include yttrium oxide (YₓO_{y}).

Each of the first and second work function patterns 107 and 108 may form a dipole at the interface with the gate dielectric layer 105. Accordingly, Gate Induced Drain Leakage (GIDL) may be prevented and hole accumulation in the channel region 103 may be reduced. Therefore, Dynamic Off Leakage deterioration that may be caused due to the floating body effect may be prevented.

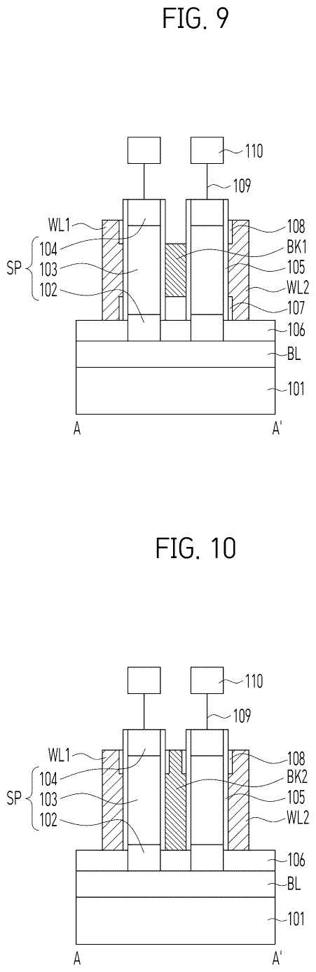

Referring to FIG. 9, a memory element 110 may be formed over a semiconductor pillar SP and the memory element 110 may be electrically connected to the substrate 101 through a storage node 109. The memory element 110 may include a capacitor.

In particular, the embodiment of the present disclosure may include a PUC (Peripheral-Under-Cell) structure. The PUC structure may be a structure in which a peripheral circuit region is formed in the lower portion of a memory cell. The PUC structure may be formed by forming a memory cell and a peripheral circuit region in substrates, individually, and then bonding the substrates with each other. Therefore, since a high-temperature process (for example, approximately 950° C. or higher) may be excluded and the diffusion of lanthanum that may be caused due to the high-temperature process may be prevented after the vertical channel transistor is formed, it is possible to maintain the first and second work function patterns 107 and 108 as they are.

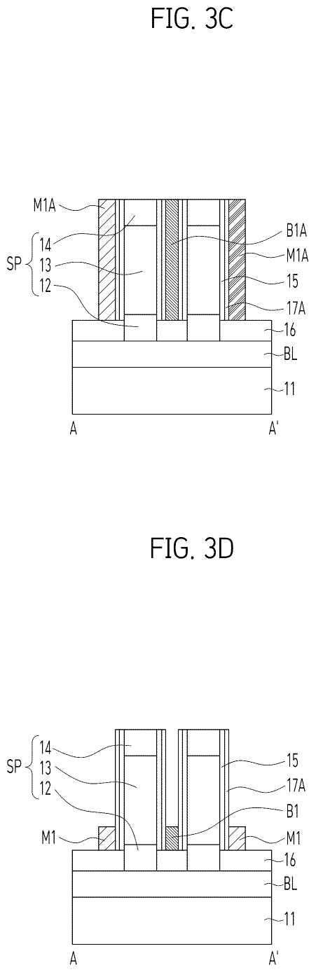

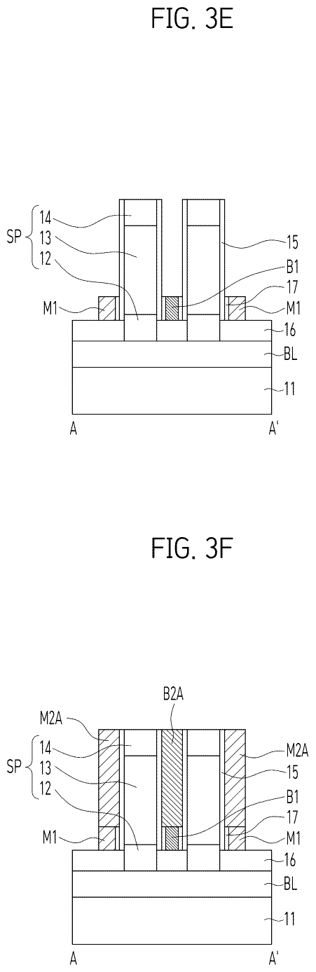

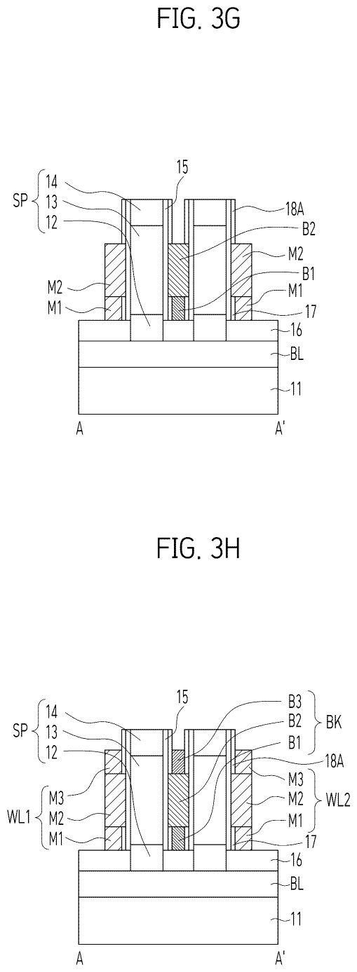

FIGS. 3A to 3I are process cross-sectional views illustrating a method for fabricating a semiconductor device in accordance with an embodiment of the present disclosure.

Referring to FIG. 3A, a bit line BL may be formed over substrate 11.

The substrate 11 may be a material appropriate for semiconductor processing. The substrate 11 may include a semiconductor substrate. The substrate 11 may be formed of a silicon-containing material. The substrate 11 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 11 may also include another semiconductor material, such as germanium. The substrate 11 may also include a III/V-group semiconductor substrate, for example, a compound semiconductor substrate, such as gallium arsenide (GaAs). The substrate 11 may also include an SOI (Silicon-On-Insulator) substrate.

A lower dielectric layer (not shown) may be formed between the substrate 11 and the bit line BL.

The bit lines BL may each extend in the second direction D2. The bit lines may also be disposed spaced apart from each other in the first direction D1 which is orthogonal to the second direction D2, as illustrated in FIG. 1. The bit lines BL may include a metal material. For example, the metal material may include titanium (Ti), titanium nitride (TiN), tantalum (Ta), tantalum nitride (TaN), molybdenum (Mo), ruthenium (Ru), tungsten (W), tungsten nitride (WN), titanium silicon nitride (TiSiN), tungsten silicon nitride (WSiN), polysilicon, or a combination thereof, however, the embodiments of the present disclosure are not limited thereto. Each bit line BL may further include a conductive barrier in the upper and lower portions thereof.

A plurality of semiconductor pillars SP may be disposed on the upper portions of the bit lines BL.

The semiconductor pillars SP may be spaced apart from each other in the upper portions of the bit lines BL. The semiconductor pillars SP may extend in a direction perpendicular to the surface of the substrate 11. Each of the semiconductor pillars SP may include a first doped region 12, a channel region 13, and a second doped region 14. The first doped region 12 and the second doped region 14 may be disposed at both ends of the semiconductor pillar SP. The channel region 13 may be disposed between the first doped region 12 and the second doped region 14. Each of the semiconductor pillars SP may have a rectangular pillar shape, however, the embodiments of the present disclosure are not limited thereto.

The semiconductor pillar SP may directly contact the bit lines BL. More specifically, the first doped region 102 of the semiconductor pillar SP may directly contact the bit line BL.

A supporting dielectric layer 16 may be formed between the semiconductor pillars SP. The supporting dielectric layer 16 may be disposed between neighboring semiconductor pillars SP. The supporting dielectric layer 16 may serve as a support that supports the semiconductor pillars SP. The height of the supporting dielectric layer 16 may be lower than the height of the first doped region 12 of the semiconductor pillar SP. The upper surface of the supporting dielectric layer 106 may be disposed at a lower level than the upper surface of the first doped region 12. For example, the supporting dielectric layer 16 may include silicon oxide, however, the embodiments of the present disclosure are not limited thereto.

The gate dielectric layer 15 may be formed on both sidewalls of the semiconductor pillar SP. The gate dielectric layer 15 may be formed through a series of processes of forming a dielectric material that covers the semiconductor pillars SP and the supporting dielectric layer 16, and performing a spacer etching process onto the dielectric material such that the dielectric material remains only on the semiconductor pillars SP. The gate dielectric layer 15 may be formed on both sidewalls of each semiconductor pillar SP over the supporting dielectric layer 16. For example, the gate dielectric layer 15 may include silicon oxide.

Referring to FIG. 3B, a first low work function inducing material 17A may be formed over the gate dielectric layer 15 on both sidewalls of the semiconductor pillar SP. For example, the first low work function inducing material 17A may include lanthanum oxide (LaO) or yttrium oxide (YₓO_{y}). The first low work function inducing material 17A may be formed, for example, by an Atomic Layer Deposition (ALD) process. The thickness of the first low work function inducing material 17A may be thinner than the thickness of the gate dielectric layer 15. The first low work function inducing material 17A may be formed by repeating the deposition cycle of the ALD process once or twice. Therefore, the thickness of the first low work function inducing material 17A may be of several angstrom (Å). For example, the thickness of the gate dielectric layer 15 may range from approximately 40 Å to 60 Å, and the first low work function inducing material 17A may be adjusted to approximately 10 Å or less.

According to another embodiment of the present disclosure, the first low work function inducing material 17A may cover the entire surface including the gate dielectric layer 15.

Referring to FIG. 3C, a first preliminary gate layer M1A and a first preliminary conductive layer B1A may be formed over the first low work function inducing material 17A. The first preliminary gate layer M1A may be disposed on the first sidewall of the semiconductor pillar SP. The first preliminary conductive layer B1A may be disposed on the second sidewall of the semiconductor pillar SP.

The first preliminary gate layer M1A and the first preliminary conductive layer B1A may be formed through a series of processes of forming a conductive material that gap-fills between the semiconductor pillars SP, and then etching the conductive material to remain over the first low work function inducing material 17A.

According to another embodiment of the present disclosure, the first preliminary gate layer M1A and the first preliminary conductive layer B1A may be formed through a series of processes of forming an inter-layer dielectric layer that gap-fills between the semiconductor pillars SP, etching the inter-layer dielectric layer to form an opening that exposes the first low work function inducing material 17A, and then gap-filling the opening with a conductive material.

The first preliminary gate layer M1A and the first preliminary conductive layer B1A may be formed simultaneously through a single process. The first preliminary gate layer M1A and the first preliminary conductive layer B1A may be formed of the same material. The first preliminary gate layer M1A and the first preliminary conductive layer B1A may include a metal material. For example, the metal material for the first preliminary gate layer M1A and the first preliminary conductive layer B1A may include a metal nitride such as titanium nitride (TiN), titanium aluminum nitride (TiAlN), tungsten nitride (WN), and tantalum nitride (TaN), or a low-resistance metal material such as tungsten (W), aluminum (Al), ruthenium (Ru), platinum (Pt), and gold (Au). According to an embodiment of the present disclosure, the metal material for the first preliminary gate layer M1A and the first preliminary conductive layer B1A may include molybdenum (Mo).

According to another embodiment of the present disclosure, the first preliminary gate layer M1A and the first preliminary conductive layer B1A may be formed sequentially through different processes. For example, after the first preliminary gate layer M1A is formed, the first preliminary conductive layer B1A may be formed, or they may be formed in the reverse order. When the first preliminary gate layer M1A is formed, a mask that exposes only the first sidewall of the semiconductor pillar SP may be applied. When the first preliminary conductive layer B1A is formed, a mask that exposes only the second sidewall of the semiconductor pillar SP may be applied.

According to another embodiment of the present disclosure, the first preliminary gate layer M1A and the first preliminary conductive layer B1A may include different metal materials. According to yet another embodiment of the present disclosure, the first preliminary gate layer M1A may include a metal material, and the first preliminary conductive layer B1A may include polysilicon.

According to an embodiment of the present disclosure, the first preliminary conductive layer B1A may be formed between the neighboring semiconductor pillars SP. The first preliminary conductive layer B1A may be formed between the semiconductor pillars SP of a pair, and the first preliminary gate layer M1A may be formed on the second sidewall of each semiconductor pillar SP.

Referring to FIG. 3D, the first metal electrode M1 and the first conductive electrode B1 may be formed. To this end, the first preliminary gate layer (M1A, see FIG. 3C) and the first preliminary conductive layer (B1A, see FIG. 3C) may be etched. The first preliminary gate layer (M1A, see FIG. 3C) and the first preliminary conductive pattern (B1A, see FIG. 3C) may be etched by a recess process.

The first metal electrode M1 and the first conductive electrode B1 may partially overlap with the first doped region 12 and the channel region 13 in a direction parallel to the top surface of the substrate 11 (also referred to as a horizontal surface). The lower surfaces of the first metal electrode M1 and the first conductive electrode B1 may be disposed at a lower level than the upper surface of the first doped region 12. The upper surfaces of the first metal electrode M1 and the first conductive electrode B1 may be disposed at a higher level than the upper surface of the first doped region 12.

Referring to FIG. 3E, a first work function pattern 17 may be formed.

The first work function pattern 17 may be formed by a wet etching process. After the first metal electrode M1 and the first conductive electrode B1 are formed, the wet etching process may be performed to remove the exposed first low work function inducing material (17A, see FIG. 3D) in the upper portions of the first metal electrode M1 and the first conductive electrode B1.

The upper surface of the first work function pattern 17 may be disposed at the same level as the upper surfaces of the first metal electrode M1 and the first conductive electrode B1. The first work function pattern 17 may partially overlap with the first doped region 12 and the channel region 13. The first work function pattern 17 may be disposed between the gate dielectric layer 15 and the first metal electrode M1. Also, the first work function pattern 17 may be disposed between the gate dielectric layer 15 and the first conductive electrode B1. The first work function pattern 17 forms a dipole at the interface with the gate dielectric layer 15 to induce a low work function of the gate electrode that overlaps with the first doped region 12, thus preventing Gate Induced Drain Leakage (GIDL). According to an embodiment of the present disclosure, the first work function pattern 17 can create a dipole at the interface with the gate dielectric layer 15. This dipole lowers the work function of the gate electrode overlapping the first doped region 12, effectively mitigating Gate Induced Drain Leakage (GIDL).

The gate dielectric layer 15 formed on both sidewalls of the semiconductor pillar SP may be exposed over the first work function pattern 17.

Referring to FIG. 3F, the second preliminary gate layer M2A and the second preliminary conductive layer B2A may be formed over the gate dielectric layer 15 which is exposed in the upper portions of the first work function pattern 17, the first metal electrode M1, and the first conductive electrode B1. The second preliminary gate layer M2A may be disposed on the first sidewall of the semiconductor pillar SP. The second preliminary conductive layer B2A may be disposed on the second sidewall of the semiconductor pillar SP.

The second preliminary gate layer M2A and the second preliminary conductive layer B2A may be formed through the same process as those of the first preliminary gate layer (M1A, see FIG. 3C) and the first preliminary conductive layer (B1A, see FIG. 3C), respectively.

The second preliminary gate layer M2A may be of the same material as that of the first metal electrode M1. The second preliminary conductive layer B2A may be of the same material as that of the first conductive electrode B1. According to another embodiment of the present disclosure, the second preliminary gate layer M2A and the second preliminary conductive layer B2A may include materials that are different from those of the first metal electrode M1 and the first conductive electrode B1, respectively.

Referring to FIG. 3G, the second metal electrode M2 and the second conductive electrode B2 may be formed. To this end, the second preliminary gate layer (M2A, see FIG. 3F) and the second preliminary conductive layer (B2A, see FIG. 3F) may be etched. The second preliminary gate layer (M2A, see FIG. 3F) and the second preliminary conductive layer (B2A, see FIG. 3F) may be etched by a recess process.

The second metal electrode M2 and the second conductive electrode B2 may overlap with the channel region 13 in the horizontal direction. The upper surfaces of the second metal electrode M2 and the second conductive electrode B2 may be disposed at a lower level than the lower surface of the second doped region 14. The second metal electrode M2 and the second conductive electrode B2 may directly contact the gate dielectric layer 15. The line widths of the second metal electrode M2 and the second conductive electrode B2 may be wider than the line widths of the first metal electrode M1 and the first conductive electrode B1.

The gate dielectric layer 15 formed on both sidewalls of the semiconductor pillar SP may be exposed in the upper portions of the second metal electrode M2 and the second conductive electrode B2.

Subsequently, a second low work function inducing material 18A may be formed over the gate dielectric layer 15 that is exposed in the upper portions of the second metal electrode M2 and the second conductive electrode B2.

The second low work function inducing material 18A may be formed by the same process as that of the first low work function inducing material (17A, see FIG. 3B). The second low work function inducing material 18A may include the same material as that of the first low work function inducing material (17A, see FIG. 3B). For example, the second low work function inducing material 18A may include lanthanum oxide (LaO) or yttrium oxide (YₓO_{y}).

The second low work function inducing material 18A may be formed, for example, by an Atomic Layer Deposition (ALD) process. The thickness of the second low work function inducing material 18A may be thinner than the thickness of the gate dielectric layer 15. The second low work function inducing material 18A may be formed by repeating the deposition cycle of the ALD process at least once or twice. Therefore, the thickness of the second low work function inducing material 18A may be of several angstrom (Å). For example, the thickness of the gate dielectric layer 15 may range from approximately 40 Å to 60 Å, and the second low work function inducing material 18A may be adjusted to approximately 10 Å or less.

According to another embodiment of the present disclosure, the second low work function inducing material 18A may cover the entire surface including the gate dielectric layer 15. The second low work function inducing material 18A may cover the upper surface of the second metal electrode M2. The second low work function inducing material 18A located on the upper surface of the second metal electrode M2 may be disposed between a third metal electrode, which is formed through the subsequent process, and the second metal electrode M2. The second low work function inducing material 18A located on the upper surface of the second metal electrode M2 may also be diffused into the upper and lower metals through the subsequent heat treatment so that it may not remain between the metal electrodes.

Referring to FIG. 3H, a third metal electrode M3 and a third conductive electrode B3 may be formed over the second low work function inducing material 18A.

The third metal electrode M3 and the third conductive electrode B3 may be formed through the same process as those of the first and second metal electrodes M1 and M2 and the first and second conductive electrodes B1 and B2, respectively.

The third metal electrode M3 may be of the same material as those of the first and second metal electrodes M1 and M2. The third conductive electrode B3 may be of the same material as those of the first and second conductive electrodes B1 and B2. According to another embodiment of the present disclosure, the third metal electrode M3 may include a material which is different from those of the first and second metal electrodes M1 and M2, and the third conductive electrode B3 may include a material which is different from those of the first and second conductive electrodes B1 and B2.

The first to third metal electrodes M1, M2 and M3 may form each of the word lines WL1 and WL2. The first to third conductive electrodes B1, B2 and B3 may form a conductive pattern BK.

According to an embodiment of the present disclosure, each of the word lines WL1 and WL2 may include a first word line WL1 and a second word line WL2. The conductive pattern BK may be disposed between the first word line WL1 and the second word line WL2. A pair of the word lines WL1 and WL2 may share one conductive pattern BK.

Referring to FIG. 3I, a second work function pattern 18 may be formed.

The upper surface of the second work function pattern 18 may be disposed at the same level as the upper surfaces of the third metal electrode M3 and the third conductive pattern B3. The second work function pattern 18 may partially overlap with the second doped region 14 and the channel region 13 in the horizontal direction. The second work function pattern 18 may be disposed between the gate dielectric layer 15 and the third metal electrode M3. Also, the second work function pattern 18 may be disposed between the gate dielectric layer 15 and the third conductive electrode B3. The second work function pattern 18 may form a dipole at the interface with the gate dielectric layer 15 to induce a low work function of the word lines WL1 and WL2 overlapping with the second doped region 14, thereby preventing Gate Induced Drain Leakage (GIDL).

FIGS. 9 to 13 are cross-sectional views illustrating semiconductor devices in accordance with other embodiments of the present disclosure. FIGS. 9 to 13 may show the same configuration as that of FIG. 2, except for the word line, the conductive pattern, and the first and second work function patterns. As for the constituent elements also appearing in FIG. 2, a description of them may be briefly provided or omitted.

Referring to FIG. 9, the semiconductor device may include a bit line BL, semiconductor pillars SP disposed spaced apart from each other over the bit line BL, a gate dielectric layer 105 surrounding the entire sidewalls of the semiconductor pillars SP, word lines WL1 and WL2 each of which is formed over the gate dielectric layer 105 on the first sidewall of the semiconductor pillars SP, and a conductive pattern BK1 formed over the gate dielectric layer 105 on the second sidewall of the semiconductor pillars SP. Also, the semiconductor device may include first and second work function patterns 107 and 108 that locally cover the gate dielectric layer 105 between the word lines WL1 and WL2 and the gate dielectric layer 105.

Each of the word lines WL1 and WL2 may be formed over the gate dielectric layer 105 on the first sidewall of the semiconductor pillars SP, respectively.

The conductive pattern BK1 may be formed over the gate dielectric layer 105 on the second sidewall of the semiconductor pillars SP. The conductive pattern BK1 may be formed between adjacent semiconductor pillars over the gate dielectric layer 105 on the second sidewall of each of the semiconductor pillars SP. The length of the conductive pattern BK1 may be shorter than the length of each word line WL1 and WL2. The conductive pattern BK1 may not overlap with the first and second doped regions 102 and 104. The lower surface of the conductive pattern BK1 may be positioned at a higher level than the upper surface of the first doped region 102, and the upper surface of the conductive pattern BK1 may be positioned at a lower level than the lower surface of the second doped region 104.

The word lines WL1 and WL2 and the conductive pattern BK1 may extend in the first direction D1 in parallel to both sidewalls of the semiconductor pillar SP.

The word lines WL1 and WL2 and the conductive pattern BK1 may include the same material. The word lines WL1 and WL2 and the conductive pattern BK1 may include a metal material, for example, a metal nitride such as titanium nitride (TiN), titanium aluminum nitride (TiAlN), tungsten nitride (WN), and tantalum nitride (TaN), or a low-resistance metal material such as tungsten (W), aluminum (Al), ruthenium (Ru), platinum (Pt), and gold (Au). According to another embodiment of the present disclosure, the metal material may include molybdenum (Mo).

According to another embodiment of the present disclosure, the word lines WL1 and WL2 and the conductive pattern BK1 may include different metal materials. According to yet another embodiment of the present disclosure, the word lines WL1 and WL2 may include a metal material, and the conductive pattern BK1 may include polysilicon. According to yet another embodiment of the present disclosure, each of the word lines WL1 and WL2 may include a stacked structure of different metal materials, as illustrated in FIG. 8.

According to an embodiment of the present disclosure, the vertical channel transistor may have a double-gate structure in which the word lines WL1 and WL2 and the conductive pattern BK are formed on both sidewalls of the semiconductor pillar SP. Each of the word lines WL1 and WL2 may be a gate electrode of the vertical channel transistor. The conductive pattern BK1 may function to shield an electric field formed by a neighboring gate, that is, the neighboring word line WL1 and WL2. Therefore, the neighboring gate effect may be minimized.

The first work function pattern 107 and the second work function pattern 108 may be formed between the gate dielectric layer 105 and the word lines WL1 and WL2, respectively.

The first work function pattern 107 may be formed to partially overlap with the first doped region 102 and the channel region 103 in the horizontal direction. The second work function pattern 108 may be formed to partially overlap with the second doped region 104 and the channel region 103 in the horizontal direction.

The first and second work function patterns 107 and 108 may include a low work function material. The first and second work function patterns 107 and 108 may include materials that may induce a low work function by forming a dipole at the interface with the gate dielectric layer 105. For example, the first and second work function patterns 107 and 108 may include a low work function inducing material (LaO). According to another embodiment of the present disclosure, the first and second work function patterns 107 and 108 may include yttrium oxide (YₓO_{y}).

Each of the first and second work function patterns 107 and 108 may form a dipole at the interface with the gate dielectric layer 105. Accordingly, Gate Induced Drain Leakage (GIDL) may be prevented and hole accumulation in the channel region 103 may be reduced. Therefore, Dynamic Off Leakage deterioration that may be caused due to the floating body effect may be prevented.

A memory element 110 may be formed over a semiconductor pillar SP and the memory element 110 may be electrically connected to the substrate 101 through a storage node 109. The memory element 110 may include a capacitor.

Also, according to an embodiment of the present disclosure, Gate Induced Drain Leakage (GIDL) may be prevented by forming the conductive pattern BK1 to have a length shorter than the length of each word line WL1 and WL2 so that it does not overlap with the first and second doped regions 102 and 104.

Referring to FIG. 10, the semiconductor device may include a bit line BL, semiconductor pillars SP disposed spaced apart from each other over the bit line BL, a gate dielectric layer 105 surrounding the entire sidewalls of the semiconductor pillars SP, word lines WL1 and WL2 each of which is formed over the gate dielectric layer 105 on the first sidewall of the semiconductor pillars SP, and a conductive pattern BK2 formed over the gate dielectric layer 105 on the second sidewall of the semiconductor pillars SP. Also, the semiconductor device may include a second work function pattern 108 that locally covers the gate dielectric layer 105 between the word lines WL1 and WL2 and the gate dielectric layer 105 and between the conductive pattern BK2 and the gate dielectric layer 105.

The word lines WL1 and WL2 may be formed over the gate dielectric layer 105 on the first sidewall of the semiconductor pillars SP. Each of the word lines WL1 and WL2 may have a lower line width which is wider than an upper line width.

The conductive pattern BK2 may be formed over the gate dielectric layer 105 on the second sidewall of the semiconductor pillars SP. The conductive pattern BK2 may be formed between a pair of adjacent semiconductor pillars SP. The conductive pattern BK2 may have a lower line width which is different from an upper line width. The conductive pattern BK2 may have a lower line width which is wider than an upper line width. The upper line width of the conductive pattern BK2 may be narrower than the upper line width of each word line WL1 and WL2.

The word lines WL1 and WL2 and the conductive pattern BK2 may extend in the first direction D1 in parallel to both sidewalls of the semiconductor pillar SP.

The word lines WL1 and WL2 and the conductive pattern BK2 may include the same material. The word lines WL1 and WL2 and the conductive pattern BK2 may include a metal material, for example, a metal nitride such as titanium nitride (TiN), titanium aluminum nitride (TiAlN), tungsten nitride (WN), and tantalum nitride (TaN), or a low-resistance metal material such as tungsten (W), aluminum (Al), ruthenium (Ru), platinum (Pt), and gold (Au). According to an embodiment of the present disclosure, the metal material for the word lines WL1 and WL2 and the conductive pattern BK2 may include molybdenum (Mo).

According to another embodiment of the present disclosure, the word lines WL1 and WL2 and the conductive pattern BK2 may include different metal materials. According to yet another embodiment of the present disclosure, the word lines WL1 and WL2 may include a metal material, and the conductive pattern BK may include polysilicon. According to yet another embodiment of the present disclosure, each of the word lines WL1 and WL2 may include a stacked structure of different metal materials, as illustrated in FIG. 8.

The second work function pattern 108 may be formed between the gate dielectric layer 105 and the word lines WL1 and WL2, and also between the gate dielectric layer 105 and the conductive pattern BK2.

The second work function pattern 108 may be formed to partially overlap with the second doped region 104 and the channel region 103 in the horizontal direction.

The second work function pattern 108 may include a low work function material. The second work function pattern 108 may include materials that may induce a low work function by forming a dipole at the interface with the gate dielectric layer 105. For example, the second work function pattern 108 may include lanthanum oxide (LaO). According to another embodiment of the present disclosure, the second work function pattern 108 may include yttrium oxide (YₓO_{y}).

Each of the second work function patterns 108 may form a dipole at the interface with the gate dielectric layer 105. Accordingly, Gate Induced Drain Leakage (GIDL) may be prevented and hole accumulation in the channel region 103 may be reduced. Therefore, Dynamic Off Leakage deterioration that may be caused due to floating body effect may be prevented.

A memory element 110 may be formed over a semiconductor pillar SP and the memory element 110 may be electrically connected to the substrate 101 through storage node 109. The memory element 110 may include a capacitor.

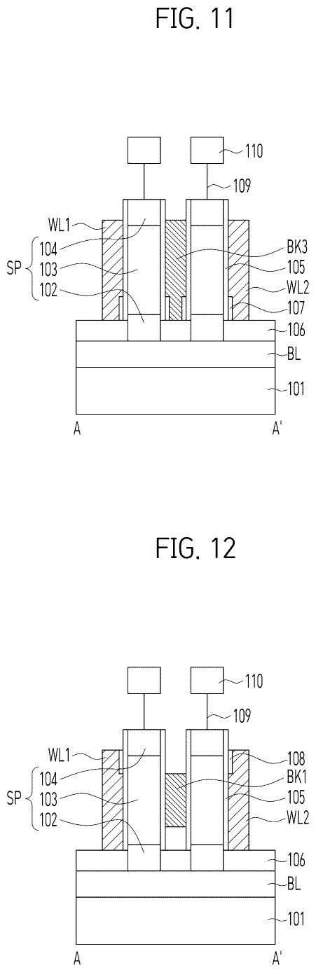

Referring to FIG. 11, the semiconductor device may include a bit line BL, semiconductor pillars SP disposed spaced apart from each other over the bit line BL, a gate dielectric layer 105 surrounding the entire sidewalls of the semiconductor pillars SP, word lines WL1 and WL2 each of which is formed over the gate dielectric layer 105 on the first sidewall of the semiconductor pillars SP, and a conductive pattern BK3 formed over the gate dielectric layer 105 on the second sidewall of the semiconductor pillars SP. Also, the semiconductor device may include a first work function pattern 107 that locally covers the gate dielectric layer 105 between the word lines WL1 and WL2 and the gate dielectric layer 105 and between the conductive pattern BK3 and the gate dielectric layer 105.

The word lines WL1 and WL2 may be formed over the gate dielectric layer 105 on the first sidewall of the semiconductor pillars SP. Each of the word lines WL1 and WL2 may have a lower line width which is narrower than an upper line width.

The conductive pattern BK3 may be formed over the gate dielectric layer 105 on the second sidewall of the semiconductor pillars SP. The conductive pattern BK3 may be formed between a pair of adjacent semiconductor pillars SP. The conductive pattern BK3 may have a lower line width which is different from an upper line width. The conductive pattern BK3 may have a lower line width which is narrower than an upper line width. The lower line width of the conductive pattern BK3 may be narrower than the lower line width of each word line WL1 and WL2.

The word lines WL1 and WL2 and the conductive pattern BK3 may extend in the first direction D1 in parallel to both sidewalls of the semiconductor pillar SP.

The word lines WL1 and WL2 and the conductive pattern BK3 may include the same material. The word lines WL1 and WL2 and the conductive pattern BK3 may include a metal material, for example, a metal nitride such as titanium nitride (TiN), titanium aluminum nitride (TiAlN), tungsten nitride (WN), and tantalum nitride (TaN), or a low-resistance metal material such as tungsten (W), aluminum (Al), ruthenium (Ru), platinum (Pt), and gold (Au). According to another embodiment of the present disclosure, the metal material may include molybdenum (Mo).

According to another embodiment of the present disclosure, the word lines WL1 and WL2 and the conductive pattern BK3 may include different metal materials. According to yet another embodiment of the present disclosure, the word lines WL1 and WL2 may include a metal material, and the conductive pattern BK3 may include polysilicon. According to yet another embodiment of the present disclosure, each of the word lines WL1 and WL2 may include a stacked structure of different metal materials, as illustrated in FIG. 8.

The first work function pattern 107 may be formed between the gate dielectric layer 105 and the word lines WL1 and WL2, and between the gate dielectric layer 105 and the conductive pattern BK3.

The first work function pattern 107 may be formed to partially overlap with the first doped region 102 and the channel region 103 in the horizontal direction.

The first work function pattern 107 may include a low work function material. The first work function pattern 107 may include materials that may induce a low work function by forming a dipole at the interface with the gate dielectric layer 105. For example, the first work function pattern 107 may include lanthanum oxide (LaO). According to another embodiment of the present disclosure, the first work function pattern 107 may include yttrium oxide (YₓO_{y}).

Each of the first work function patterns 107 may form a dipole at the interface with the gate dielectric layer 105. Accordingly, Gate Induced Drain Leakage (GIDL) may be prevented and hole accumulation in the channel region 103 may be reduced. Therefore, Dynamic Off Leakage deterioration that may be caused due to the floating body effect may be prevented.

A memory element 110 may be formed over the semiconductor pillar SP and may be electrically connected through storage node 109 to the semiconductor pillar SP. The memory element 110 may include a capacitor.

Referring to FIG. 12, the semiconductor device may include a bit line BL, semiconductor pillars SP disposed spaced apart from each other over the bit line BL, a gate dielectric layer 105 surrounding the entire sidewalls of the semiconductor pillars SP, word lines WL1 and WL2 each of which is formed over the gate dielectric layer 105 on the first sidewall of the semiconductor pillars SP, and a conductive pattern BK1 formed over the gate dielectric layer 105 on the second sidewall of the semiconductor pillars SP. Also, the semiconductor device may include a second work function pattern 108 that locally covers the gate dielectric layer 105 between the word lines WL1 and WL2 and the gate dielectric layer 105.

The word lines WL1 and WL2 may be formed over the gate dielectric layer 105 on the first sidewall of the semiconductor pillars SP. Each of the word lines WL1 and WL2 may have a lower line width which is wider than an upper line width.

The conductive pattern BK1 may be formed over the gate dielectric layer 105 on the second sidewall of the semiconductor pillars SP. The length of the conductive pattern BK1 may be shorter than the length of each word line WL1 and WL2. The conductive pattern BK1 may not overlap with the first and second doped regions 102 and 104. The lower surface of the conductive pattern BK1 may be higher than the upper surface of the first doped region 102, and the upper surface of the conductive pattern BK1 may be lower than the lower surface of the second doped region 104.

The word lines WL1 and WL2 and the conductive pattern BK1 may extend in the first direction D1 in parallel to both sidewalls of the semiconductor pillar SP.

The word lines WL1 and WL2 and the conductive pattern BK1 may include the same material. The word lines WL1 and WL2 and the conductive pattern BK1 may include a metal material, for example, a metal nitride such as titanium nitride (TiN), titanium aluminum nitride (TiAlN), tungsten nitride (WN), and tantalum nitride (TaN), or a low-resistance metal material such as tungsten (W), aluminum (Al), ruthenium (Ru), platinum (Pt), and gold (Au). According to another embodiment of the present disclosure, the metal material may include molybdenum (Mo).

According to another embodiment of the present disclosure, the word lines WL1 and WL2 and the conductive pattern BK1 may include different metal materials. According to yet another embodiment of the present disclosure, the word lines WL1 and WL2 may include a metal material, and the conductive pattern BK1 may include polysilicon. According to yet another embodiment of the present disclosure, each of the word lines WL1 and WL2 may include a stacked structure of different metal materials, as illustrated in FIG. 8.

According to an embodiment of the present disclosure, the vertical channel transistor may have a double gate structure in which the word lines WL1 and WL2 and the conductive pattern BK are formed on both sidewalls of the semiconductor pillar SP. Each of the word lines WL1 and WL2 may be a gate electrode of the vertical channel transistor. The conductive pattern BK1 may function to shield an electric field formed by a neighboring gate, that is, the neighboring word line WL1 and WL2. Therefore, the neighboring gate effect may be minimized.

The second work function pattern 108 may be formed between the gate dielectric layer 105 and the word lines WL1 and WL2.

The second work function pattern 108 may be formed to partially overlap with the second doped region 104 and the channel region 103 in the horizontal direction.

The second work function pattern 108 may include a low work function material. The first and second work function patterns 108 may include materials that may induce a low work function by forming a dipole at the interface with the gate dielectric layer 105. For example, the second work function pattern 108 may include lanthanum oxide (LaO). According to another embodiment of the present disclosure, the second work function pattern 108 may include yttrium oxide (YₓO_{y}).

Each of the second work function patterns 108 may form a dipole at the interface with the gate dielectric layer 105. Accordingly, Gate Induced Drain Leakage (GIDL) may be prevented and hole accumulation in the channel region 103 may be reduced. Therefore, Dynamic Off Leakage deterioration that may be caused due to the floating body effect may be prevented.

A memory element 110 may be formed over the semiconductor pillar SP and the memory element 110 may be electrically connected to the substrate 101 through the storage node 109. The memory element 110 may include a capacitor.

Also, according to the embodiment of the present disclosure, it is possible to prevent Gate Induced Drain Leakage (GIDL) by forming the conductive pattern BK1 to have a length which is shorter than the length of each word line WL1 and WL2 so that the conductive pattern BK1 does not overlap with the first and second doped regions 102 and 104.

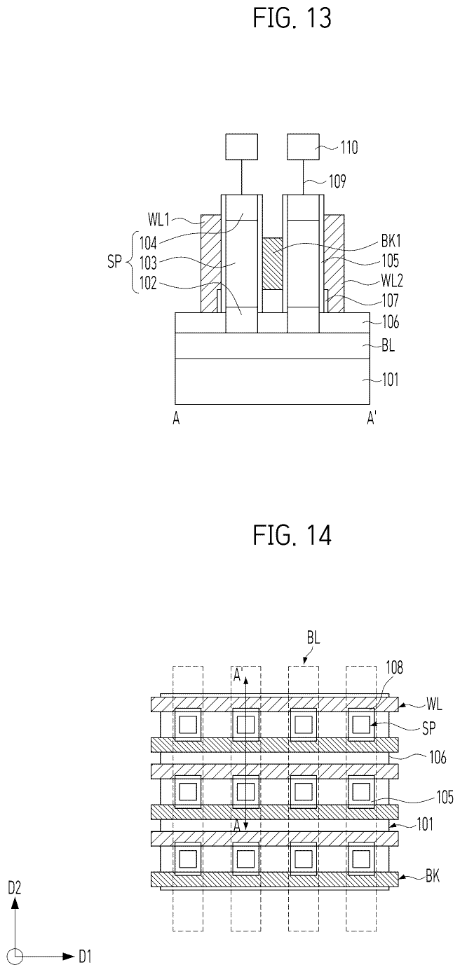

Referring to FIG. 13, the semiconductor device may include a bit line BL, semiconductor pillars SP disposed spaced apart from each other over the bit line BL, a gate dielectric layer 105 surrounding the entire sidewalls of the semiconductor pillars SP, word lines WL1 and WL2 each of which is formed over the gate dielectric layer 105 on the first sidewall of the semiconductor pillars SP, and a conductive pattern BK1 formed over the gate dielectric layer 105 on the second sidewall of the semiconductor pillars SP. Also, the semiconductor device may include a first work function pattern 107 that locally covers the gate dielectric layer 105 between the word lines WL1 and WL2 and the gate dielectric layer 105.

The word lines WL1 and WL2 may be formed over the gate dielectric layer 105 on the first sidewall of the semiconductor pillars SP. Each of the word lines WL1 and WL2 may have a lower line width which is narrower than an upper line width.

The conductive pattern BK1 may be formed over the gate dielectric layer 105 on the second sidewall of the semiconductor pillars SP. The length of the conductive pattern BK1 may be shorter than the length of each word line WL1 and WL2. The conductive pattern BK1 may not overlap with the first and second doped regions 102 and 104. The lower surface of the conductive pattern BK1 may be higher than the upper surface of the first doped region 102, and the upper surface of the conductive pattern BK1 may be lower than the lower surface of the second doped region 104.

The word lines WL1 and WL2 and the conductive pattern BK1 may extend in the first direction D1 in parallel to both sidewalls of the semiconductor pillar SP.

The word lines WL1 and WL2 and the conductive pattern BK1 may include the same material. The word lines WL1 and WL2 and the conductive pattern BK1 may include a metal material, for example, a metal nitride such as titanium nitride (TiN), titanium aluminum nitride (TiAlN), tungsten nitride (WN), and tantalum nitride (TaN), or a low-resistance metal material such as tungsten (W), aluminum (Al), ruthenium (Ru), platinum (Pt), and gold (Au). According to another embodiment of the present disclosure, the metal material may include molybdenum (Mo).

According to another embodiment of the present disclosure, the word lines WL1 and WL2 and the conductive pattern BK1 may include different metal materials. According to yet another embodiment of the present disclosure, the word lines WL1 and WL2 may include a metal material, and the conductive pattern BK1 may include polysilicon. According to yet another embodiment of the present disclosure, each of the word lines WL1 and WL2 may include a stacked structure of different metal materials, as illustrated in FIG. 8.

According to this embodiment of the present disclosure, the vertical channel transistor may have a double-gate structure in which the word lines WL1 and WL2 and the conductive pattern BK are formed on both sidewalls of the semiconductor pillar SP. Each of the word lines WL1 and WL2 may be a gate electrode of the vertical channel transistor. The conductive pattern BK1 may serve to shield an electric field formed by a neighboring gate, that is, the neighboring word line WL1 and WL2. Therefore, the neighboring gate effect may be minimized.

The first work function pattern 107 may be formed between the gate dielectric layer 105 and the word lines WL1 and WL2.

The first work function pattern 107 may be formed to partially overlap with the first doped region 102 and the channel region 103.

The first work function pattern 107 may include a low work function material. The first work function pattern 107 may include materials that may induce a low work function by forming a dipole at the interface with the gate dielectric layer 105. For example, the first work function pattern 107 may include lanthanum oxide (LaO). According to another embodiment of the present disclosure, the first work function pattern 107 may include yttrium oxide (YₓO_{y}).

Each of the first function patterns 107 may form a dipole at the interface with the gate dielectric layer 105. Accordingly, Gate Induced Drain Leakage (GIDL) may be prevented and hole accumulation in the channel region 103 may be reduced. Therefore, Dynamic Off Leakage deterioration that may be caused due to the floating body effect may be prevented.

A memory element 110 may be formed over the semiconductor pillar SP and the memory element 110 may be electrically connected to the substrate 101 through the storage node 109. The memory element 110 may include a capacitor.

Also, according to the embodiment of the present disclosure, it is possible to prevent Gate Induced Drain Leakage (GIDL) by forming the conductive pattern BK1 to have a length which is shorter than the length of each word line WL1 and WL2 so that the conductive pattern BK1 does not overlap with the first and second doped regions 102 and 104.

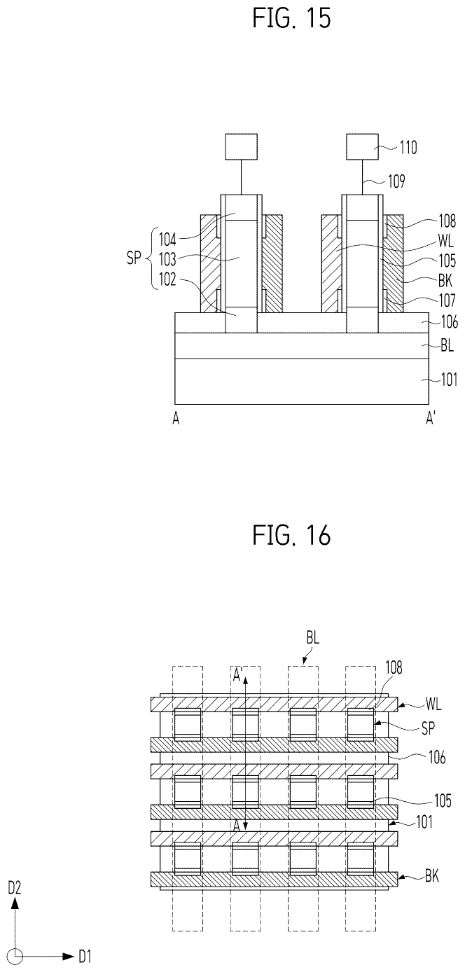

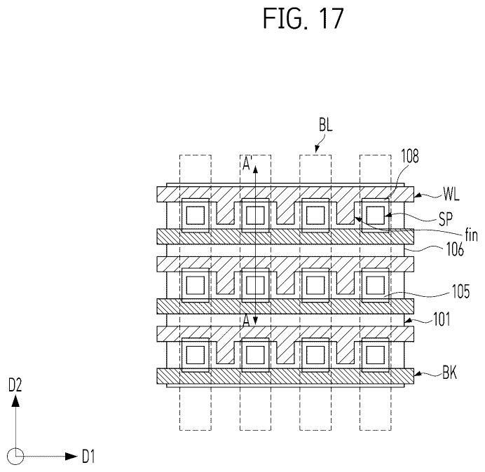

FIG. 14 is a plan view illustrating a semiconductor device in accordance with another embodiment of the present disclosure. FIG. 15 is a cross-sectional view of the semiconductor device taken along a line A-A′ shown in FIG. 14. FIGS. 16 and 17 are plan views illustrating a semiconductor device in accordance with other embodiments of the present disclosure. FIGS. 14 to 17 may be similar to FIGS. 1 and 2 except for the arrangement of the word line and the conductive pattern. The same drawing reference numerals are given to the same areas, and for the sake of convenience, a description of the same reference numerals may be briefly provided or omitted.

Referring to FIGS. 14 and 15, the semiconductor device may include a semiconductor pillar SP having doped regions respectively formed at both ends thereof, a gate dielectric layer 105 formed on both sidewalls of the semiconductor pillar SP, a word line WL formed over the gate dielectric layer 105 on a first side of the semiconductor pillar SP, and a conductive pattern BK formed over the gate dielectric layer 105 on a second side of the semiconductor pillar SP. Also, the semiconductor device may further include first and second work function patterns 107 and 108 locally formed between the word line WL and the gate dielectric layer 105 and between the conductive pattern BK and the gate dielectric layer 105.

The substrate 101 may be a material appropriate for semiconductor processing. The substrate 101 may include a semiconductor substrate.

A plurality of bit lines BL may be disposed over the substrate 101. Each of the bit lines BL may extend in the second direction D2 and may be spaced apart from each other in the first direction D1 which is orthogonal to the second direction D2.

A plurality of semiconductor pillars SP may be disposed over the bit lines BL. The semiconductor pillars SP may be spaced apart from each other in the second direction D2. The semiconductor pillars SP may have a matrix arrangement in which they are disposed spaced apart by a predetermined interval in the first direction D1 and the second direction D2.

Each semiconductor pillar SP may extend in a direction perpendicular to the top surface of the substrate 101.

Each semiconductor pillar SP may include a first doped region 102 and a second doped region 104 at both ends thereof. Each semiconductor pillar SP may include a channel region 103 disposed between the first doped region 102 and the second doped region 104. According to an embodiment of the present disclosure, each semiconductor pillar SP may have a rectangular pillar shape, however, the embodiments of the present disclosure are not limited thereto. The semiconductor pillars SP may directly contact the bit lines BL. The first doped regions 102 of the semiconductor pillars SP may directly contact the bit lines BL.

A supporting dielectric layer 106 may be formed between the semiconductor pillars SP.

The gate dielectric layer 105 may be disposed between the semiconductor pillar SP and the word line WL. The gate dielectric layer 105 may be disposed between the semiconductor pillar SP and the conductive pattern BK. For example, the gate dielectric layer 105 may include silicon oxide.

The gate dielectric layer 105 may be shaped to surround the entire side surface of the semiconductor pillar SP. The gate dielectric layer 105 may be formed with a uniform thickness on the entire side surface of the semiconductor pillar SP.

According to other embodiments of the present disclosure, the gate dielectric layer 105 may be formed only on both sidewalls of the semiconductor pillar SP, as illustrated in FIG. 16. The gate dielectric layer 105 may be disposed only between the semiconductor pillar SP and the word line WL, or between the semiconductor pillar SP and the conductive pattern BK.

Referring to FIG. 16, the gate dielectric layer 105 may be formed with the same thickness on both sidewalls of the semiconductor pillar SP. The thickness of the gate dielectric layer 105 formed between the semiconductor pillar SP and the word line WL may be the same as the thickness of the gate dielectric layer 105 formed between the semiconductor pillar SP and the conductive pattern BK.

According to another embodiment of the present disclosure, the gate dielectric layer 105 may be formed with different thicknesses on both sidewalls of the semiconductor pillar SP, as illustrated in FIGS. 5 and 6.

The word line WL may be formed over the gate dielectric layer 105 on the first sidewall of the semiconductor pillars SP. The word line WL may extend in the first direction D1 and may be spaced apart from each other in the second direction D2.

The conductive pattern BK may be formed over the gate dielectric layer 105 on the second sidewall of the semiconductor pillars SP. The conductive pattern BK may extend in the first direction D1 and may be spaced apart from each other in the second direction D2.

The word line WL and the conductive pattern BK may extend in the first direction D1 in parallel to both sidewalls of the semiconductor pillar SP. The word line WL and the conductive pattern BK may have a line shape extending in the first direction D1.

According to another embodiment of the present disclosure, as illustrated in FIG. 17, the word line WL may include a fin extending between the semiconductor pillars SP.

The word line WL and the conductive pattern BK may include the same material. The word line WL and the conductive pattern BK may include a metal material, for example, a metal nitride such as titanium nitride (TiN), titanium aluminum nitride (TiAlN), tungsten nitride (WN), and tantalum nitride (TaN), or a low-resistance metal material such as tungsten (W), aluminum (Al), ruthenium (Ru), platinum (Pt), and gold (Au). According to another embodiment of the present disclosure, the metal material may include molybdenum (Mo).

According to another embodiment of the present disclosure, the word line WL and the conductive pattern BK may include different metal materials. According to yet another embodiment of the present disclosure, the word line WL may include a metal material, and the conductive pattern BK may include polysilicon.

According to yet another embodiment of the present disclosure, the word line WL may include a stacked structure of different metal materials, such as the first and second word lines WL1 and WL2 illustrated in FIG. 8.

According to this embodiment of the present disclosure, the vertical channel transistor may have a double-gate structure in which the word line WL and the conductive pattern BK are formed on both sidewalls of the semiconductor pillar SP. The word line WL may be a gate electrode of the vertical channel transistor. The conductive pattern BK may serve to shield an electric field formed by a neighboring gate, i.e., a neighboring word line WL. Therefore, the neighboring gate effect may be minimized.

In particular, the embodiment of the present disclosure may include work function patterns 107 and 108 locally formed between the gate dielectric layer 105 and the word line WL. The work function patterns 107 and 108 may be formed between the gate dielectric layer 105 and the word line WL, and between the gate dielectric layer 105 and the conductive pattern BK.

The work function patterns 107 and 108 may include a first work function pattern 107 and a second work function pattern 108. The first work function pattern 107 may be formed to partially overlap with the first doped region 102 and the channel region 103. The second work function pattern 108 may be formed to partially overlap with the second doped region 104 and the channel region 103 in the horizontal direction.

The first and second work function patterns 107 and 108 may include a low work function material. The first and second work function patterns 107 and 108 may include materials that may induce a low work function by forming a dipole at the interface with the gate dielectric layer 105. For example, the first and second work function patterns 107 and 108 may include lanthanum oxide (LaO). According to another embodiment of the present disclosure, the first and second work function patterns 107 and 108 may include yttrium oxide (YₓO_{y}).

Each of the first and second work function patterns 107 and 108 may form a dipole at the interface with the gate dielectric layer 105. Accordingly, Gate Induced Drain Leakage (GIDL) may be prevented and hole accumulation in the channel region 103 may be reduced. Therefore, Dynamic Off Leakage deterioration that may be caused due to the floating body effect may be prevented.

A memory element 110 may be formed over a substrate 101 and the memory element 110 may be electrically connected to the substrate 101 through the storage node 109. The memory element 110 may include a capacitor.

In particular, the embodiment of the present disclosure may include a PUC (Peripheral-Under-Cell) structure. The PUC structure may be a structure in which a peripheral circuit region is formed in the lower portion of a memory cell. The PUC structure may be formed by forming a memory cell and a peripheral circuit region in substrates, individually, and then bonding the substrates with each other. Therefore, since a high-temperature process (for example, approximately 950° C. or higher) may be excluded and the diffusion of lanthanum that may be caused due to the high-temperature process may be prevented after the vertical channel transistor is formed, it is possible to maintain the first and second work function patterns 107 and 108 as they are.

According to the embodiment of the present disclosure, there is an effect of preventing the Gate Induced Drain Leakage (GIDL) by applying a work function pattern that partially overlaps with a doped region and a channel.

While the embodiments of the present disclosure have been described with respect to the specific embodiments, it will be apparent to those skilled in the art that various changes and modifications may be made without departing from the concepts and scope of the invention as defined in the following claims. Furthermore, the embodiments may be combined to form additional embodiments.

What is claimed is:

1. A semiconductor device, comprising:
a semiconductor pillar formed over a substrate;
a word line formed on a first sidewall of the semiconductor pillar;
a conductive pattern formed on a second sidewall of the semiconductor pillar; and
a work function pattern locally formed between the semiconductor pillar and the word line.

2. The semiconductor device of claim 1, wherein the semiconductor pillar includes a pair of a first semiconductor pillar and a second semiconductor pillar,
wherein the conductive pattern is formed between the first semiconductor pillar and the second semiconductor pillar, and
wherein facing sidewalls of the first semiconductor pillar and the second semiconductor pillar are respectively adjacent to facing sidewalls of the conductive pattern.

3. The semiconductor device of claim 2, wherein the word line includes a pair of a first word line and a second word line.

4. The semiconductor device of claim 3, wherein the first and second word lines are formed on first sidewalls of the first and second semiconductor pillars that are not adjacent to the conductive pattern, respectively.

5. The semiconductor device of claim 1, wherein the semiconductor pillar includes
a first doped region and a second doped region at both ends thereof, and
a channel region disposed between the first and second doped regions.

6. The semiconductor device of claim 5, wherein the work function pattern includes a first work function pattern that partially overlaps with the first doped region and the channel region in a horizontal direction parallel to a top surface of the substrate, or
the work function pattern includes a second work function pattern that partially overlaps with the second doped region and the channel region in the horizontal direction.

7. The semiconductor device of claim 1, wherein the work function pattern includes lanthanum oxide or yttrium oxide.

8. The semiconductor device of claim 1, wherein a length of the conductive pattern is equal to or shorter than a length of the word line.

9. The semiconductor device of claim 1, wherein the conductive pattern does not overlap with the first and second doped regions.

10. The semiconductor device of claim 1, further comprising
a work function pattern locally formed between the semiconductor pillar and the conductive pattern.

11. The semiconductor device of claim 10, further comprising
a gate dielectric layer formed between the semiconductor pillar and the word line and between the semiconductor pillar and the conductive pattern.

12. The semiconductor device of claim 11, wherein the gate dielectric layer is formed between the work function pattern and the semiconductor pillar.

13. The semiconductor device of claim 11, wherein a thickness of the work function pattern is thinner than a thickness of the gate dielectric layer.

14. The semiconductor device of claim 11, wherein the gate dielectric layer surrounds an entire side surface of the semiconductor pillar.

15. The semiconductor device of claim 11, wherein the gate dielectric layer is formed on both sidewalls of the semiconductor pillar contacting the conductive pattern and the word line.

16. The semiconductor device of claim 11, wherein a thickness of the gate dielectric layer between the word line and the semiconductor pillar is different from a thickness of the gate dielectric layer between the conductive pattern and the semiconductor pillar.

17. The semiconductor device of claim 1, wherein the word line includes a single metal or a stacked structure of different metal materials.

18. The semiconductor device of claim 1, wherein the word line and the conductive pattern include the same material.

19. The semiconductor device of claim 1, wherein the word line has a line shape extending in a first direction, and
the word line further includes a fin protruding in a second direction which is orthogonal to the first direction.

20. A semiconductor device comprising:
a substrate;
a plurality of bit lines spaced apart from each other in a first direction over the substrate, each bit line extending in a second direction that is orthogonal to the first direction;
at least one pair of spaced apart semiconductor pillars comprising a first and a second semiconductor pillar each extending vertically from a corresponding bit line;
word lines formed on a first sidewall of each of the semiconductor pillars;
a conductive pattern formed between the first and second semiconductor pillars;
gate dielectric layers disposed between each semiconductor pillar and conductive pattern; and
work function patterns locally formed between each gate dielectric layer and the word lines, and also between each gate dielectric layer and the conductive pattern,
wherein the work function patterns include a first work function pattern and a second work function pattern, the first work function pattern partially overlapping with a first doped region and a channel region of each semiconductor pillar, and the second work function pattern partially overlapping with a second doped region and the channel region of each semiconductor pillar in a horizontal direction parallel to a top surface of the substrate.
